(19) United States
(12) Patent Application Publication
(10) Pub. No.: US 2011/0204434 A1
(43) Pub. Date: Aug. 25, 2011

(54) SEMICONDUCTOR DEVICE AND METHOD OF FABRICATING THE SAME

(76) Inventors: SEUNGHUN SON, Yongin-si (KR); Dongil Bae, Bupyeong-gu (KR); Jongchol Kim, Seoul (KR); Seong-Cheol Paek, Suwon-si (KR)

(21) Appl. No.: 12/955,084

(22) Filed: Nov. 29, 2010

(30) Foreign Application Priority Data
Feb. 19, 2010 (KR) 10-2010-0015304

(51) Int. Cl. H01L 29/78

(52) U.S. Cl. 257/327; 257/E29.255

(57) ABSTRACT

Provided are a semiconductor device and a method of fabricating the same. The semiconductor device includes, a gate structure having a gate dielectric layer, a gate electrode, and a spacer, which are each formed on a substrate, a first impurity area formed in a portion of the substrate located below the spacer, a second impurity area in contact with a sidewall of the first impurity area and formed in the substrate on both sides of the gate structure, and a dielectric pattern in contact with a portion of the first impurity area and formed on a sidewall of the second impurity area. At this time, the second impurity area may include an upper part with an upward-narrowing width and a lower part with a downward-narrowing width.

### CROSS-REFERENCE TO RELATED APPLICATIONS

This U.S. non-provisional patent application claims priority under 35 U.S.C. §119 to Korean Patent Application 10-2010-0015304, filed on Feb. 19, 2010, the disclosure of which is hereby incorporated by reference in it's entirety.

### BACKGROUND

The present disclosure herein relates to a semiconductor device and a method of fabricating the same, and more particularly, to a semiconductor device including an impurity region and a method of fabricating the same.

With an improvement of a semiconductor device in integration, a minimum line width of a gate has gradually become reduced to improve the speed of the semiconductor device and to miniaturize the size of the semiconductor device. As the line width of the gate is reduced, the threshold voltage may also be significantly decreased due to a short channel effect. Consequently, this may lead to difficulties such as a punch through or a Drain Induced Barrier Lowering (DIBL). To overcome the above-mentioned difficulties, a halo region has been used, but the reliability of the semiconductor device may still be deteriorated as the electric field may be increased in the vicinity of channels.

### SUMMARY

The present disclosure may provide a semiconductor device which can prevent difficulties such as a short channel effect without a halo region.

The present disclosure may also provide a method of enhancing the semiconductor device.

Embodiments of the inventive concept provide a semiconductor device. The semiconductor device includes: a gate structure having a gate dielectric layer, a gate electrode, and a spacer, which are each formed on a substrate, a first impurity area formed in a portion of the substrate located below the spacer, a second impurity area in contact with a sidewall of the first impurity area and formed in the substrate on both sides of the gate structure and a dielectric pattern in contact with a portion of the first impurity area and formed on a sidewall of the second impurity area. In this case, the second impurity area may include an upper part with an upward-narrowing width and a lower part with a downward-narrowing width.

In some embodiments, the dielectric pattern may include a material selected from the group consisting of oxides, nitrides, or oxynitrides.

In other embodiments, an upper part of the second impurity area may have a positive sidewall slope and a lower part of the second impurity area may have a negative sidewall slope.

In still other embodiments, the first impurity area may be fanned so as to contact with an upper sidewall of the second impurity area, and the dielectric pattern may be formed on a lower sidewall of the second impurity area and in contact with a lower portion of the first impurity area.

In even other embodiments, a depth of the second impurity area may be deeper than a depth of the first impurity area.

In yet other embodiments, the first and second impurity areas may include the same conductive impurity.

In further embodiments, the substrate may include a conductive impurity different from the conductive impurity of the first impurity area.

In still further embodiments, the gate structure may further include a mask formed on the gate electrode.

Embodiments of the inventive concept also provide a method of fabricating a semiconductor device. The method includes: forming a gate structure having a gate dielectric layer, a gate electrode, and a spacer on a substrate, forming a first impurity area in a portion of the substrate located below the spacer, forming a recess region exposing a sidewall of the first impurity area by etching the substrate on both sides of the gate structure, forming a dielectric pattern on an inner sidewall of a lower part of the recess region while exposing a side of the first impurity area and forming a second impurity area burying an inner part of the recess region. In this case, the recess region may include an upper part and the lower part, wherein the upper part of the recess region has an upward-narrowing width and the lower part of the recess region has a downward-narrowing width.

In other embodiments, the forming of the first impurity area may include: ion-implanting impurities into the substrate on both sides of the spacer, forming a preliminary first impurity area by diffusing the impurities to a portion of the substrate located below the spacer and etching the gate dielectric layer and the portion of the substrate exposed by the gate structure using the gate structure as an etching mask to form the first impurity area and wherein the recess region is formed at a same time as the first impurity area is formed.

In still other embodiments, the gate dielectric layer and the portion of the substrate exposed by the gate structure may be etched by an isotropic etching process.

In even other embodiments, the forming of the dielectric pattern may include: forming conformally a dielectric layer inside the recess region, forming a preliminary dielectric pattern on an inner sidewall of the recess region by anisotropically etching the dielectric layer, forming a first buried layer burying the lower part of the recess region, and etching selectively the preliminary dielectric pattern exposed on the inner sidewall of the upper part of the recess region to form the dielectric pattern. In still other embodiments, the forming of the second impurity area may include forming a second buried layer burying an upper part of the recess region to form the second impurity area having the first and second buried layers.

In yet other embodiments, the dielectric layer may be formed by a thermal oxidation process and the dielectric layer may contain silicon oxide, and the substrate may contain silicon.

In further embodiments, the preliminary dielectric pattern, which is exposed on the inner sidewall of the upper part of the recess region, may selectively be etched by an isotropic etching process.

In still further embodiments, the first buried layer may be formed by a primary epitaxial growth process using the substrate as a seed.

In even further embodiments, the second buried layer may be formed by a secondary epitaxial growth process using the first buried layer as a seed.

In yet further embodiments, the forming of the dielectric pattern may include: forming conformally a dielectric layer inside the recess region and on the gate electrode, forming a preliminary dielectric pattern on an inner sidewall of the recess region and a sidewall of the spacer by anisotropically etching the dielectric layer, forming a first buried layer burying the lower part of the recess region, and etching selectively the preliminary dielectric pattern exposed on the inner sidewall of the upper part of the recess region and a sidewall of the spacer to form the dielectric pattern. In still other embodiments, the forming of the second impurity area may include forming a second buried layer burying an upper part of the recess region to form the second impurity area having the first and second buried layers.

In yet further embodiments, the dielectric layer may be formed by a chemical vapor deposition process or an atomic layer deposition process.

In yet further embodiments, the dielectric layer may be formed by using a material selected from the group consisting of oxides, nitrides, or oxynitrides.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIGS. 1A through 1L, are cross-sectional views illustrating a method of fabricating a semiconductor device according to an exemplary embodiment of the inventive concept;

FIGS. 2A through 2D are cross-sectional views illustrating a method of fabricating a semiconductor device according to an exemplary embodiment of the inventive concept;

FIG. 3A is an enlarged view illustrating a part of a semiconductor device fabricated in accordance with an exemplary embodiment of the inventive concept;

FIGS. 3B and 3C are graphs illustrating the electric characteristics of the semiconductor device shown in FIG. 3A;

FIG. 4A is a block diagram illustrating a memory card including the semiconductor device according to an exemplary embodiment of the inventive concept; and

FIG. 4B is a block diagram illustrating an information processing system including the semiconductor device according to an exemplary embodiment of the inventive concept.

### DETAILED DESCRIPTION OF PREFERRED EMBODIMENTS

Exemplary embodiments now will be described more fully hereinafter by referring to the accompanying drawings, in which exemplary embodiments are shown. This inventive concept may, however, be embodied in many different forms and should not be construed as limited to the exemplary embodiments set forth therein. Rather, these exemplary embodiments are provided so that this inventive concept will be thorough and complete, and will fully convey the scope of this inventive concept to those skilled in the art.

In the specification, if it is mentioned that a certain constituent is on another constituent, it means that the constituent may be directly formed on another constituent or a third constituent may be formed therebetween. In addition, in the drawings, the thickness of the constituent is exaggerated for the effective description of the technical contents.

The embodiments described in the specification will be explained by referring to the ideal and exemplary cross-sectional views and/or the plan views. In the drawings, the thicknesses of the layers and the areas are exaggerated for the effective description of the technical contents. Accordingly, the contents of the exemplary drawings may be modified in accordance with the fabrication method and/or the allowance. Accordingly, the exemplary embodiments of the inventive concept are not limited to the particular contents shown in the drawings, but include the contents of the modification in accordance with the fabrication process. For example, the perpendicularly shown etching area may be round or have a predetermined curvature. Accordingly, the areas shown in the drawings have properties, and the shapes of the areas shown in the drawings are for the purpose of describing particular shapes only and are not intended to be limiting of the scope of this inventive concept. In various embodiments of the specification, the terminologies of the first, second, etc. are used to describe the constituents. However, these constituents are not limited to the terminologies, and these terminologies are merely used to distinguish a certain constituent from another constituent. The embodiments illustrated and shown herein include the complementary embodiments thereof.

The terminology used in the specification is for the purpose of describing particular embodiments only and is not intended to be limiting of this inventive concept. In the specification, the singular forms are intended to include the plural forms as well, unless the context clearly indicates otherwise. It will be further understood that the terms “comprises” and/or “comprising”, or “includes” and/or “including”, do not preclude the presence or addition of one or more other elements.

Hereinafter, the embodiments of the inventive concept will be described in detail by referring to the drawings.

### First Embodiment

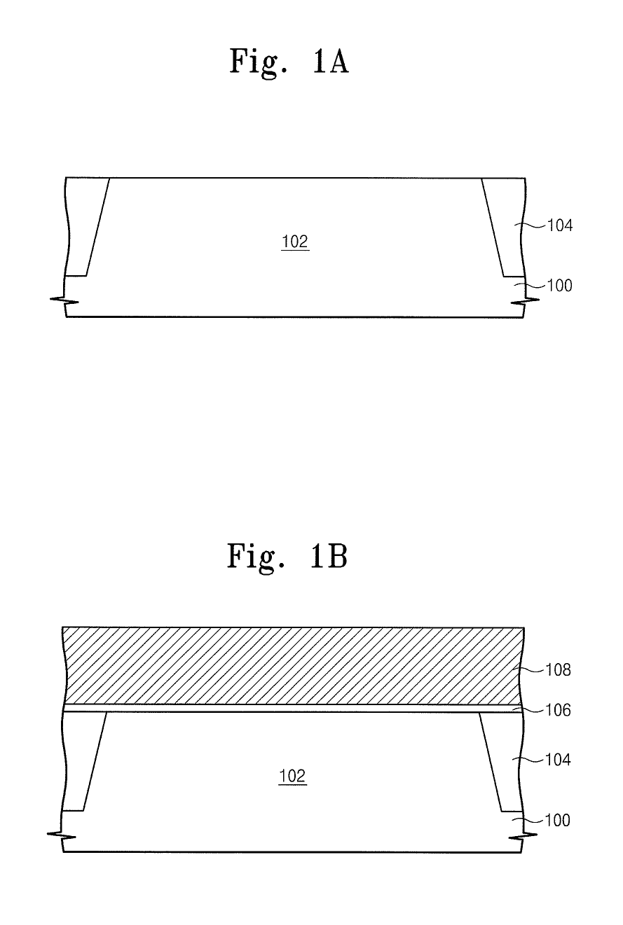

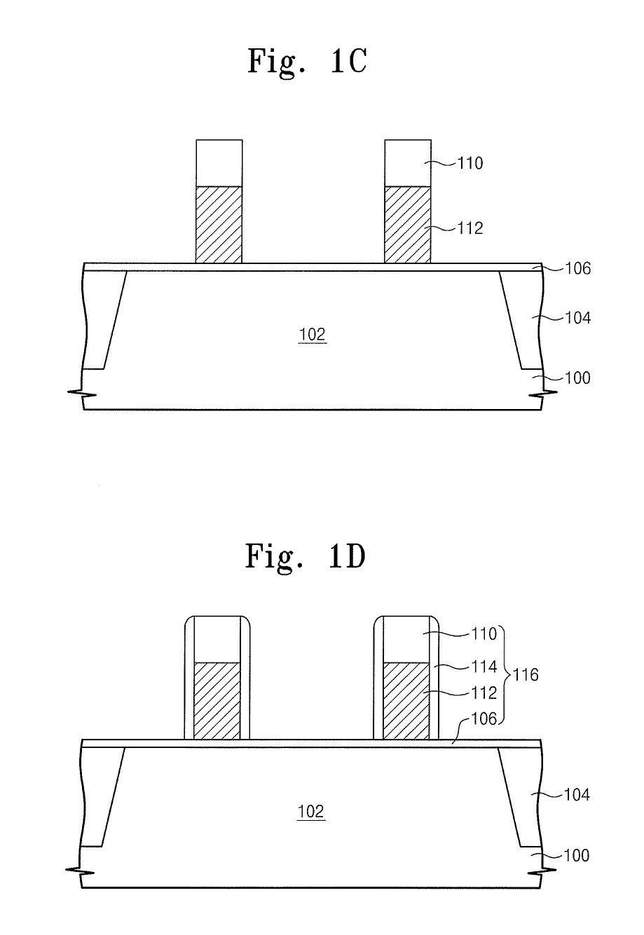

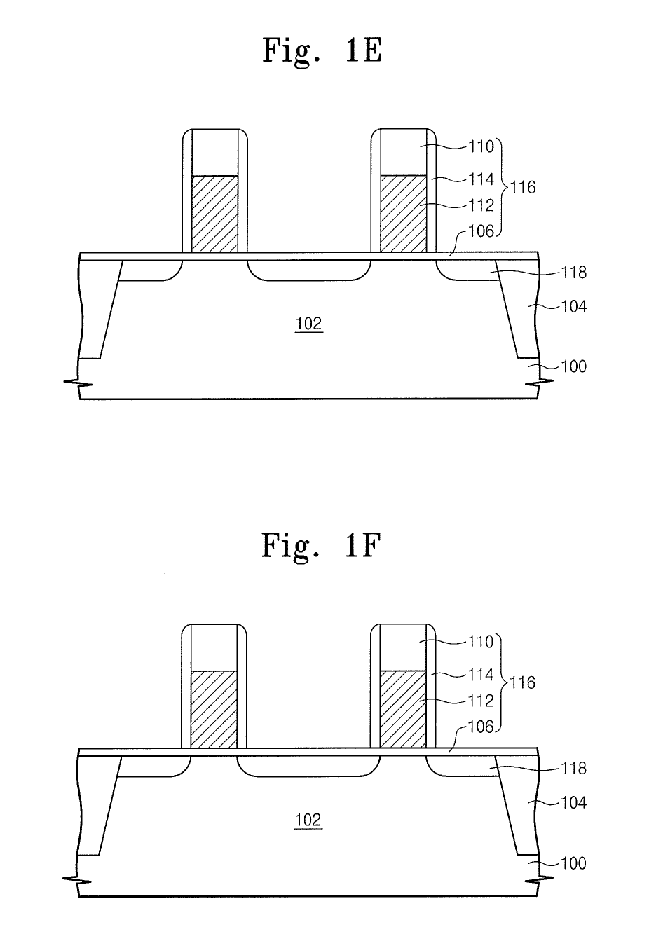

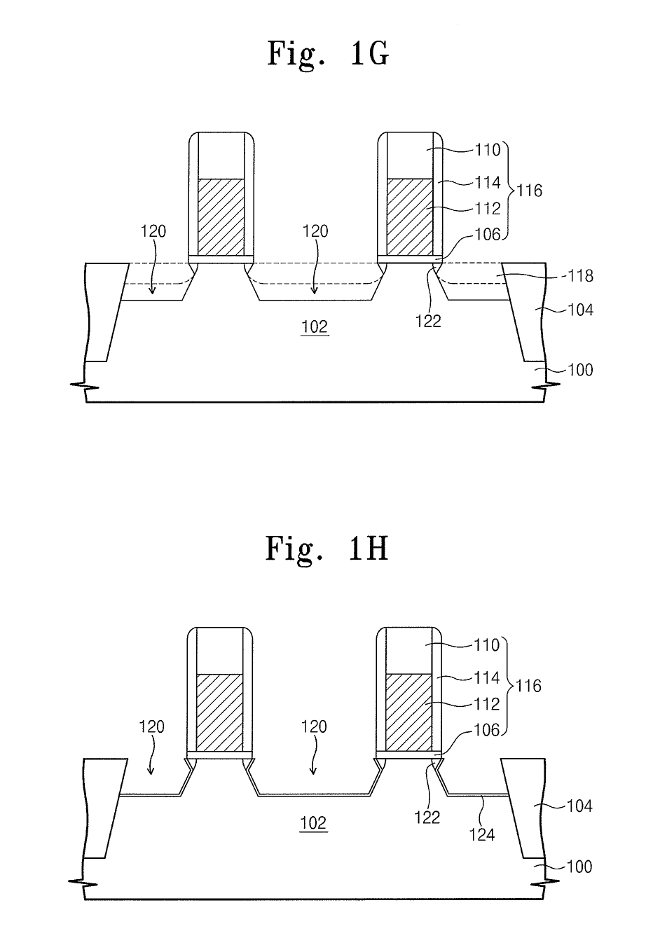

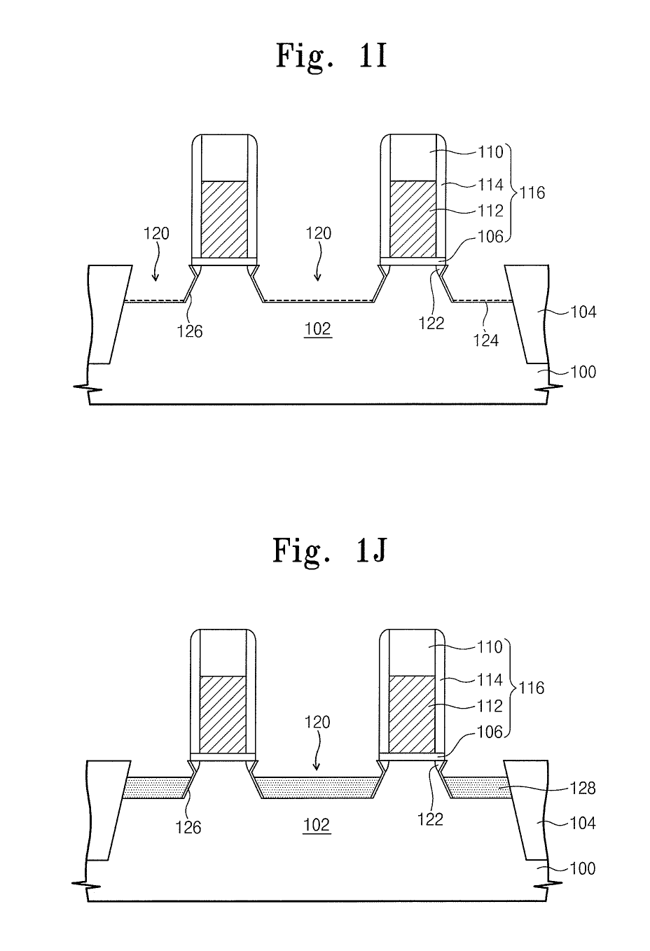

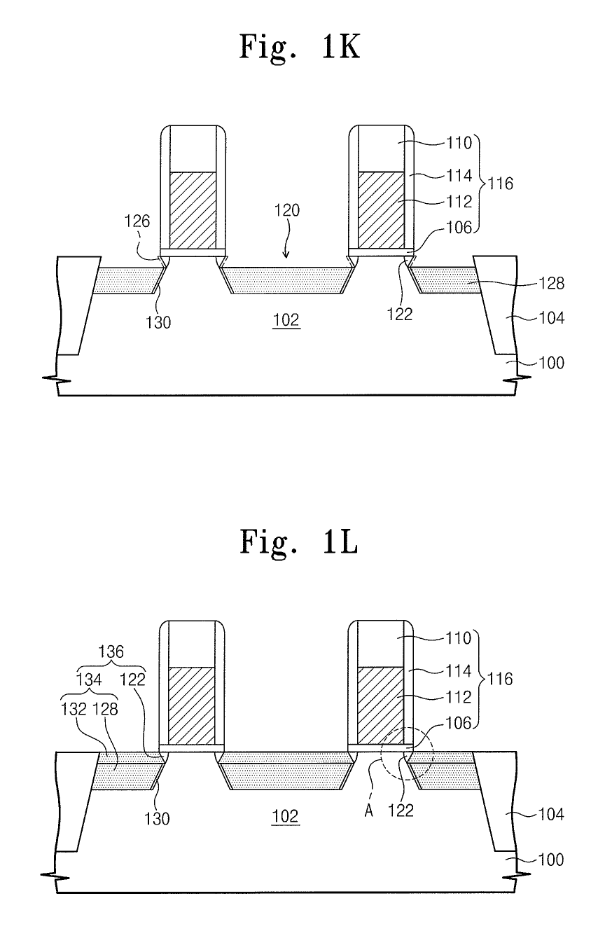

FIGS. 1A through 1L are cross-sectional views illustrating a method of fabricating a semiconductor device according to an exemplary embodiment of the inventive concept.

Referring to FIG. 1A, a field area 104 may be formed on a substrate 100 to define an active area 102. For example, the active area 102 may extend in a first direction.

Examples of the substrate 100 may include but are not limited to a silicon (Si) substrate, a germanium (Ge) substrate, and a silicon-germanium (Si—Ge) substrate, an SOI (silicon-on-insulator) substrate, a GOI (germanium-on-insulator) substrate, and an SGOI (silicon-germanium-on-insulator) substrate.

The substrate 100 may be used which is doped with first conductive-type impurities. According to embodiments of the inventive concept, a substrate doped with p-type impurities may be used as the substrate 100. Examples of the p-type impurities may include but are not limited to boron (B), gallium (Ga), and indium (In).

The field area 104 may be formed in a shallow trench isolation process. In addition, the field area 104 may contain oxides such as, for example, silicon oxides. Examples of the silicon oxides may include but are not limited to BSG (Borosilicate Glass), PSG (PhosphoSilicate Glass), BPSG (BoroPhosphoSilicate Glass), PE-TEOS (Plasma Enhanced Tetra Ethyl Ortho Silicate), and HDP (High Density Plasma) oxides.

Referring to FIG. 1B, a gate dielectric layer 106 and a conductive layer 108 may be formed on the substrate 100.

As an example, the gate dielectric layer 106 may contain but is not limited to silicon oxides. In this case, the gate dielectric layer 106 may be formed by, for example, chemical vapor deposition or thermal oxidization.

As another example, the gate dielectric layer 106 may contain but is not limited to metal oxides. Examples of the metal oxides may include but are not limited to tantalum oxides, titanium oxides, hafnium oxides, zirconium oxides, aluminum oxides, niobium oxides, cesium oxides, yttrium oxides, indium oxides, and iridium oxides. The gate dielectric layer 106 may have, for example, a laminate structure. In this case, the gate dielectric layer 106 may be formed by, for example, chemical vapor deposition, atomic layer deposition, or metal-organic chemical vapor deposition.

The conductive layer 108 may be formed on the gate dielectric layer 106.

The conductive layer 108 may contain, for example, silicon doped with impurities, metal, or metal compounds. For example, the conductive layer 108 may contain tungsten, tantalum, titanium, aluminum, copper, titanium silicide, or cobalt silicide. The conductive layer 108 may use one thereof or a combination thereof. In addition, the conductive layer 108 may have a single-layered structure or a multi-layered structure. The conductive layer 108 may be formed by, for example, physical vapor deposition, chemical vapor deposition, or silicidation.

Referring to FIG. 1C, gate electrodes 112 and a mask 110 may be formed on the gate dielectric layer 106.

For example, the mask 110 (see FIG. 1B) may be formed on the conductive layer 108. The mask 110 contains nitrides such as, for example, silicon nitrides. The gate electrodes 112 may be foamed on the gate dielectric layer 106 by patterning the conductive layer 108 through etching by use of the mask 110. The gate electrodes 112 may extend in a second direction substantially different from the first direction. For example, the first and second directions may be perpendicular to each other.

The mask 110 may be used in etching, as described above, or may be used to protect the gate electrodes 112 and to isolate other structures from the gate electrodes 112 in the subsequent process.

Referring to FIG. 1D, a spacer 114 may be formed on the side surface of the mask 110 and the gate electrode 112.

For example, a nitride layer may be conformally formed on the substrate 100 in which the gate dielectric layer 106, the gate electrodes 112, and the mask 110 are formed. The nitride layer may contain silicon nitrides. The nitride layer, which is formed on the upper parts of the mask 110 and the gate dielectric layer 106, may be selectively etched by subjecting the nitride layer to, for example, anisotropic etching. Accordingly, the spacer 114 is formed on the side surface of the mask 110 and the gate electrode 112.

In this way, it is possible to foam a gate structure 116 including the gate dielectric layer 106, the gate electrodes 112, the mask 110, and the spacers 114 on the substrate 100.

Referring to FIG. 1E, preliminary first impurity areas 118 may be formed on the surface of the substrate 100 exposed and adjacent to both sides of the gate structure 116.

Each of the preliminary first impurity areas 118 may be formed by implanting ions into second impurities of second conductive type. The second conductive-type impurities may be substantially different from the first conductive-type impurities. For example, the second impurities may be n-type impurities. Examples of the n-type impurities may include but are not limited to phosphorus (P) and arsenic (As).

Referring to FIG. 1F, the preliminary first impurity area 118 may be diffused.

According to the embodiment of the inventive concept, the preliminary first impurity area 118 may be expanded downward and laterally. For example, the preliminary first impurity area 118 may be diffused to the substrate 100 located below the spacers 114 by the lateral expansion. In addition, the preliminary first impurity area 118 may contain impurities with first density.

Generally, the impurity implanting process and the impurity diffusing process may be simultaneously performed. Accordingly, the processes of FIGS. 1E and 1F may be considered as one process.

Referring to FIG. 1G, a recess region 120 may be formed on the substrate 100 by using the gate structure 116 as an etching mask.

According to embodiments of the inventive concept, the gate dielectric layer 106 may be etched which is exposed to both sides of the gate structure 116. Subsequently, the substrate 100 may be etched which is exposed to both sides of the gate structure 116. The processes of etching the gate dielectric layer 106 and the substrate 100 may be considered as one process, and the etching may be, for example, isotropic etching.

For example, when the substrate 100 contains silicon, the gate dielectric layer 106 may contain oxides, and the mask 110 and the spacer 114 may contain nitrides, and the isotropic etching may be performed using an etchant having high etching selectivity with respect to silicon and nitrides. Accordingly, the mask 110 and the spacer 114 may not be substantially etched, while the gate dielectric layer 106 and the substrate 100 are partially etched.

Because of the nature of the isotropic etching, the substrate 100 located directly below the spacer 114 may be slowly etched. Accordingly, the recess region 120 may include an upper part with an upward-narrowing width and a lower part with a downward-narrowing width.

The preliminary first impurity area 118 may be partially etched during the formation of the recess region 120, and thus a first impurity area 122 may be formed. For example, the recess region 120 may be etched substantially more deeply than the preliminary first impurity area 118. Accordingly, the preliminary first impurities 118 exposed by the gate structure 116 may be etched, thereby forming the first impurity area 122. One side of the first impurity area 122 may be exposed by the upper part of the inner wall in the recess region 120.

Referring to FIG. 1H, a dielectric layer 124 may be conformally formed in the recess region 120.

According to several embodiments of the inventive concept, the dielectric layer 124 may be formed by, for example, thermal oxidization. The thermal oxidization may be performed thanks to excellent reactivity of the silicon and oxygen. When the substrate 100 contains silicon, silicon exposed to the inside of the recess region 120 may be selectively oxidized upon supplying oxygen and applying heat to the substrate 100. At this time, the dielectric layer 124 may contain silicon oxides.

Referring to FIG. 1I, the dielectric layer 124 may be etched to form a preliminary dielectric pattern 126 on the inner wall of the recess region 120.

According to some embodiments of the inventive concept, the dielectric layer 124 may be subjected to anisotropic etching by using the gate structure 116 as an etching mask. Examples of the anisotropic etching may include but are not limited to plasma etching and reactive ion etching. The dielectric layer 124 on the bottom surface of the recess region 120 may be selectively etched by the anisotropic etching. Accordingly, a preliminary dielectric pattern 126 may be formed on the inner wall of the recess region 120. The preliminary dielectric pattern 126 may be formed to cover the first impurity area 122.

Referring to FIG. 1J, the first buried layer 128 may be formed which buries the recess region 120.

According to some embodiments of the inventive concept, the first buried layer 128 may be formed by a primary epitaxial growth process using the substrate 100 as a seed. The first buried layer 128 may be formed so as not to cover the upper part of the recess region 120. By not covering the upper part of the recess region 120 with the first buried layer 128, the upper part of the preliminary dielectric pattern 126 may be exposed.

The first buried layer 128 may contain third impurities of the second conductive type. For example, the third impurities may be n-type impurities. As an example, the first buried layer 128 may be formed by forming a first silicon layer through the primary epitaxial growth process and ion-implanting the third impurities. As another example, the first buried layer 128 may be formed by implanting the third impurities during the primary epitaxial growth process. As still another example, the first buried layer 128 may be formed together with a second buried layer by ion-implanting third impurities into the first and second silicon layers after a subsequent process of forming a second silicon layer of the second buried layer.

Referring to FIG. 1K, the preliminary dielectric pattern 126 may be etched to form a dielectric pattern 130 exposing one side of the first impurity area 122.

According to embodiments of the inventive concept, the preliminary dielectric pattern 126 exposed by the first buried layer 128 may be etched. The etching may be, for example, isotropic etching.

For example, when the first buried layer 128 contains silicon, the preliminary dielectric pattern 126 contains oxides, and the mask 110 and the spacer 114 contain nitrides, and the isotropic etching may be performed using an etchant having high selectivity with respect to oxides. Accordingly, the first buried layer 128, the mask 110, and the spacer 114 may not be substantially etched, while the preliminary dielectric pattern 126 is partially etched.

According to another embodiment, when the gate dielectric layer 106 and the field area 104 contain the oxides, the gate dielectric layer 106 and the field area 104 may be partially etched during the isotropic etching.

Referring FIG. 1L, a second buried layer 132 may be formed which buries the upper part of the recess region 120. Therefore, a second impurity area 134 may be formed which includes the first and second buried layers 128 and 132.

According to some embodiments of the inventive concept, the second buried layer 132 may be formed by a secondary epitaxial growth process using silicon of the first buried layer 128 as a seed. The upper surface of the second buried layer 132 may be substantially level with the upper surface of the substrate 100.

The second buried layer 132 may contain fourth impurities of the second conductive type. The fourth impurities may contain, for example, n-type impurities. As an example, the second buried layer 132 may be formed by forming a second silicon layer through the secondary epitaxial growth process and ion-implanting the fourth impurities. As another example, the second buried layer 132 may be formed by ion-implanting the fourth impurities during the secondary epitaxial growth process.

The second impurity area 134 may have a density substantially higher than that of the first impurity area 122. The first impurity area 122 may have a density lower than that of the second impurity area 134. Therefore, the first impurity area 122 may have an LDD (Lightly Doped Drain) structure.

According to embodiments of the inventive concept, the first impurity area 122 and the second impurity area 134 may function as a source/drain area 136.

In this way, a transistor may be formed which includes the gate dielectric layer 106, the gate electrode 112, the mask 110, the spacer 114, the dielectric pattern 130, and the source/drain area 136. As the transistor has the dielectric pattern 130, it is possible to prevent punch through without halo region, and to improve DIBL (Drain Induced Barrier Lowering). As an area where the source/drain area 136 comes into contact with the active area 102 may be decreased by the dielectric pattern 130, it is possible to overcome the difficulty with junction leakage.

### Second Embodiment

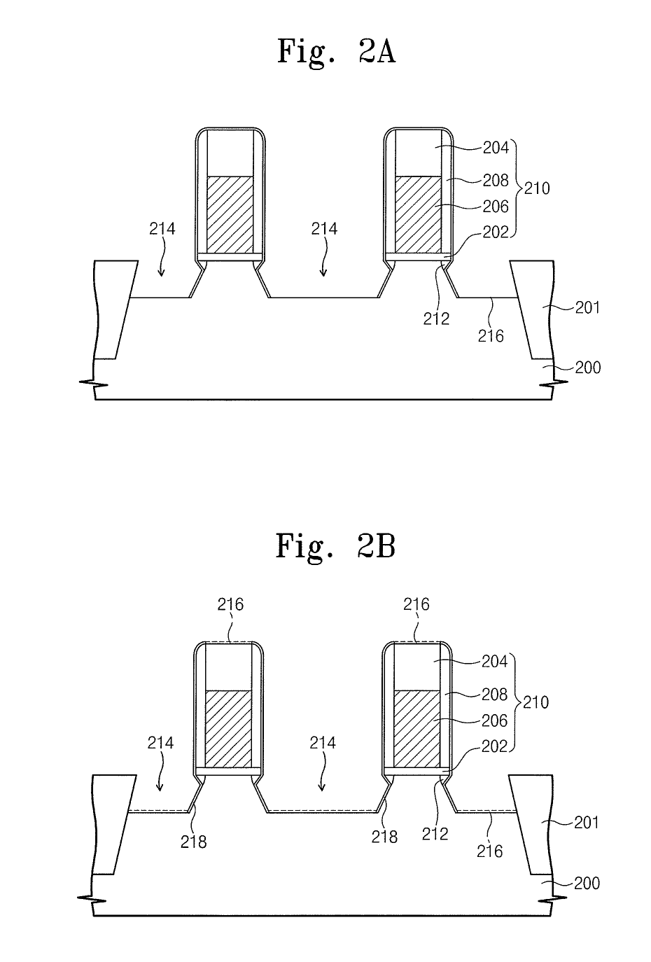

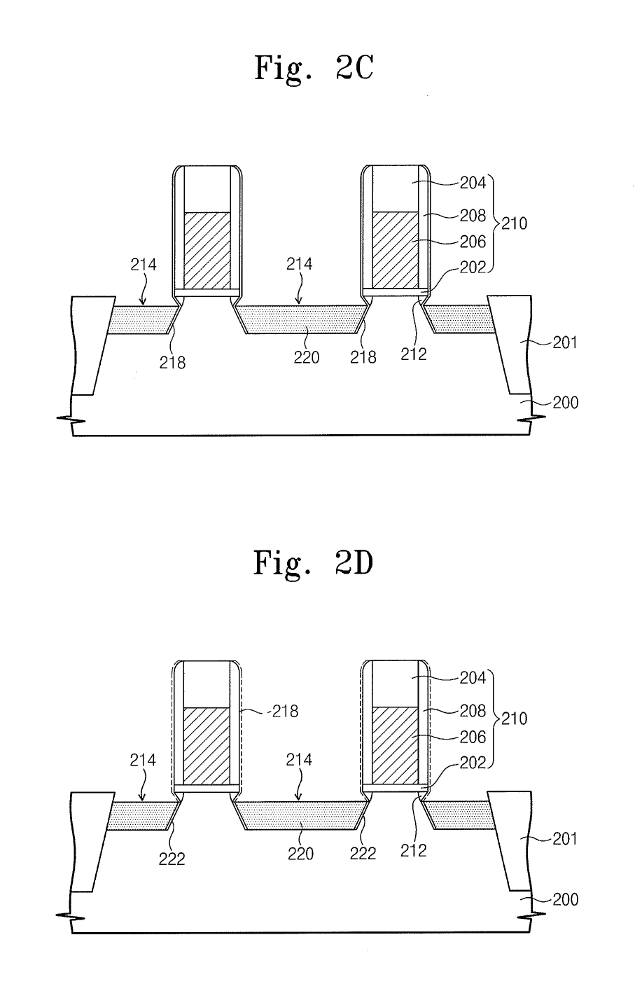

FIGS. 2A through 2D are cross-sectional views illustrating a method of fabricating a semiconductor device according to another embodiment of the inventive concept.

Referring to FIG. 2A, a gate structure 210, a first impurity area 212, and a recess region 214 may be formed on a substrate 200.

The gate structure 210 may include a gate dielectric layer 202, a mask 204, gate electrodes 206, and spacers 208.

A dielectric layer 216 may be conformally formed on the substrate 200 in which the gate structure 210, the first impurity area 212, and the recess region 214 are formed. The dielectric layer 216 may be formed continuously along the surface of the gate structure 210 and the surface of the substrate 200 in which the recess region 214 is formed. Moreover, the dielectric layer 216 may be formed so as not to bury the recess region 214.

According to several embodiments of the inventive concept, the dielectric layer 216 may contain, for example, oxides, nitrides, or oxynitrides, which may be silicon oxides, silicon nitrides, or silicon oxynitrides, respectively. In this case, the dielectric layer 216 may be formed by, for example, chemical vapor deposition or atomic layer deposition.

Referring to FIG. 2B, a preliminary dielectric pattern 218 may be formed by etching the dielectric layer 216 having the recess region 214 formed on the bottom surface thereof.

According to embodiments of the inventive concept, the dielectric layer 216, which is formed on the bottom surface of the recess region 214, may be etched by, for example, anisotropic etching. At this time, the dielectric layer 216, which is formed on the upper surface of the gate structure 210, may be etched together with the dielectric layer 216 formed on the bottom surface of the recess region 214 by, for example, the anisotropic etching. An example of the anisotropic etching may include but is not limited to plasma etching or reactive ion etching.

The preliminary dielectric pattern 218 may be formed to extend to the inner wall of the recess region 214 and the outer wall of the gate structure 210. The first impurity area 212 may be covered with the preliminary dielectric pattern 218 formed on the inner wall of the recess region 214.

Referring to FIG. 2C, a first buried layer 220 may be formed which buries the lower part of the recess region 214.

The preliminary dielectric pattern 218, which is formed on the upper inner wall of the recess region 214 and the sidewall of each of the spacers 208, may be exposed by the first buried layer 220.

Referring to FIG. 2D, the preliminary dielectric pattern 218 may be etched to form a dielectric pattern 222 exposing one side of the first impurity area 212.

According to embodiments of the inventive concept, the preliminary dielectric pattern 218 exposed by the first buried layer 220 may be etched. The part of the etched preliminary dielectric pattern 218 may be the preliminary dielectric pattern 218 formed on the sidewall of the spacer 208 and the preliminary dielectric pattern 218 exposed to the upper part of the inner wall of the recess region 214. The etching may be, for example, isotropic etching.

For example, when the first buried layer 220 contains silicon, the preliminary dielectric pattern 218 contains oxides, and the mask and spacer 208 contain nitrides, and the isotropic etching may be performed by an using etchant having high etching selectivity with respect to oxides. Accordingly, the first buried layer 220, the mask 204, and the spacer 208 may not be substantially etched, while the preliminary dielectric pattern 218 is partially etched.

According to another embodiment of the inventive concept, when the gate dielectric layer 202 and the field area 201 contain oxides, the gate dielectric layer 202 and the field area 201 may be partially etched during the isotropic etching.

In this way, it is possible to form a transistor including the gate structure 210, the dielectric pattern 222, and a source/drain on the substrate 200. When the detailed description of the second embodiment (FIGS. 2A to 2D) of the inventive concept is the substantial same as that of the first embodiment (FIGS. 1A to 1L) of the inventive concept, the detailed description is omitted.

### Example

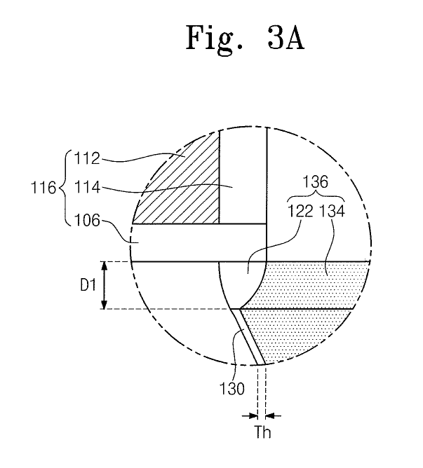

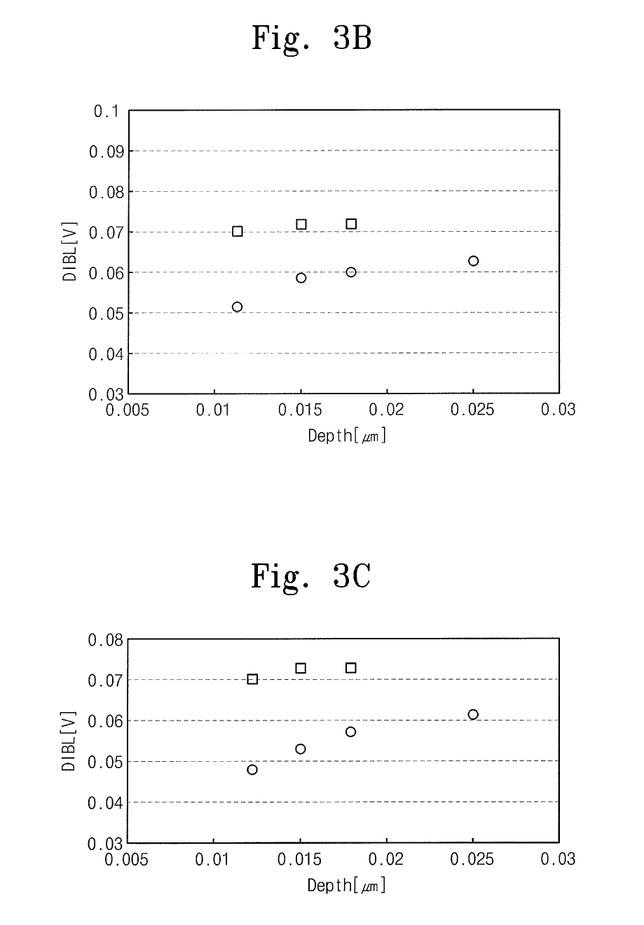

FIG. 3A is an enlarged view illustrating a part of a semiconductor device fabricated in accordance with the embodiments of the inventive concept. FIGS. 3B and 3C are graphs illustrating an electric characteristic of the semiconductor device shown in FIG. 3A. In particular, the enlarged part of FIG. 3A corresponds to FIG. 2A.

Referring to FIG. 3A, there is provided a semiconductor device including the gate structure 116, the dielectric pattern 130, and the source/drain area 136. The source/drain area 136 includes the first impurity area 122 and the second impurity area 134. The first impurity area 122 is located below the spacer 114 of the gate structure 116. The second impurity area 134 is electrically connected to the first impurity area 122 and is formed on the surface on both sides of the gate structure 116. The dielectric pattern 130 is formed on the sidewall of the second impurity area 134.

The X axis of FIGS. 3B and 3C indicates the depth of the first impurity area 122 and the unit thereof is μm. The Y axis of FIGS. 3B and 3C indicates DIBL (Drain Induced Barrier Lowering) of the semiconductor device and the unit thereof is V.

In FIG. 3B, the round dot -- indicates the degree of a variation in DIBL depending on the thickness (D1) of the first impurity area 122 of the semiconductor device including the dielectric pattern 130 with about 0.01 μm (Th). The square dot -▪- indicates the degree of a variation in DIBL changed depending on the thickness (D1) of the first impurity area 122 of the semiconductor device including no dielectric pattern 130. It is found out that the DIBL characteristic of the semiconductor device including the dielectric pattern 130 with about 0.01 μm is improved by about 26% more than the semiconductor device including no dielectric pattern 130. In addition, it is found out that the DIBL characteristic of the semiconductor device including the dielectric pattern 130 with about 0.01 μm may deteriorate with an increase in thickness (D1) of the first impurity area 122.

In FIG. 3C, the round dot -- indicates the degree of a variation in DIBL depending on accordance with the thickness (D1) of the first impurity area 122 of the semiconductor device including the dielectric pattern 130 with about 0.03 μm (Th). The square dot -▪- indicates the degree of a variation in DIBL depending on the thickness (D1) of the first impurity area 122 of the semiconductor device including no dielectric pattern 130. It is found out that the DIBL characteristic of the semiconductor device including the dielectric pattern 130 with about 0.03 μm is improved by about 33% more than the semiconductor device including no dielectric pattern 130. In addition, it is found out that the DIBL characteristic of the semiconductor device including the dielectric pattern 130 with about 0.03 μm may deteriorate with an increase in thickness (D1) of the first impurity area 122.

Referring to FIGS. 3B and 3C, it can be known that the DIBL characteristic is improved with an increase in the thickness (Th) of the dielectric pattern 130. In addition, it can be confirmed that the DIBL characteristic may deteriorate as the thickness (D1) of the first impurity area 122 of the semiconductor device including the dielectric pattern 130 increases.

### Applications

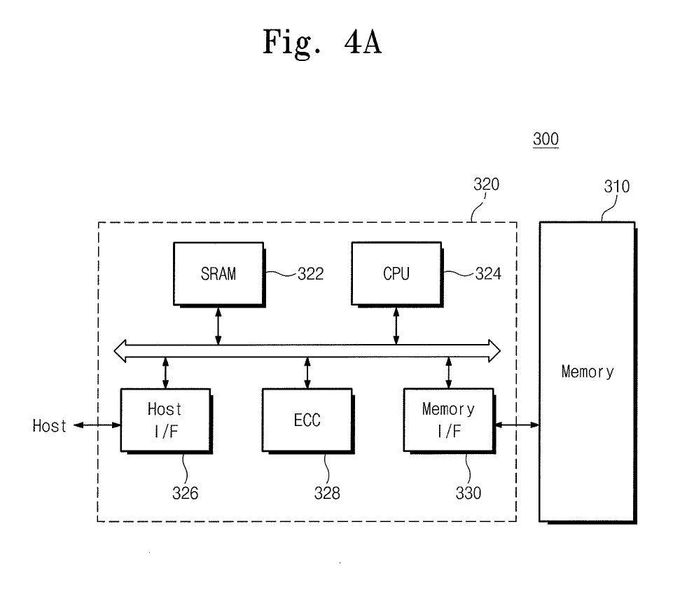

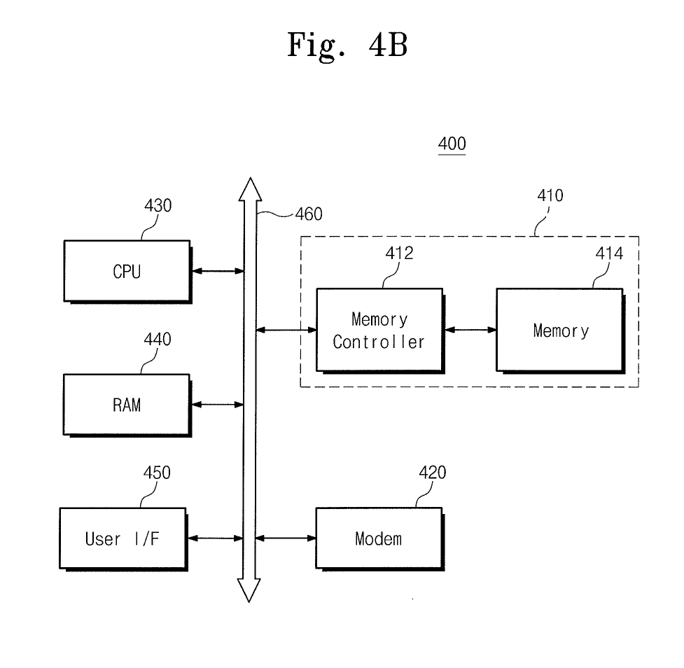

FIG. 4A is a block diagram illustrating a memory card including the semiconductor device according to an embodiment of the inventive concept.

Referring to FIG. 4A, a memory, which includes the semiconductor device fabricated according to the above-described embodiment of the inventive concept, may be applied to a memory card 300. As an example, the memory card 300 may include a memory controller 320 controlling a general data exchange between a host and a memory 310. A Static random access memory (SRAM) 322 may be used as an operational memory of a central processing unit 324. A host interface 326 may have a data exchange protocol of the host connected to the memory card 300. An error correction code 328 may detect and correct errors contained in data read out from the memory 310. A memory interface 330 interfaces with the memory 310. The central processing unit 324 may perform a general control operation of a data exchange of the memory controller 320.

The memory 310 applied to the memory card 300 includes the semiconductor device fabricated according to the embodiments of the inventive concept. Accordingly, it is possible to prevent the difficulties of punch through, drain induced barrier lowering, and junction leakage. Therefore, it is possible to improve the reliability of the memory including the semiconductor device.

FIG. 4B is a block diagram illustrating an information processing system including the semiconductor device according to an embodiment of the inventive concept.

Referring to FIG. 4B, an information processing system 400 may include a memory system 410 including the semiconductor device according to the embodiment of the inventive concept. The information processing system 400 may include a mobile device and a computer. As an example, the information processing system 400 may include the memory system 410, a modem 420, a central processing unit 430, a random access memory (RAM) 440, and a user interface 450 which are electrically connected to a system bus 460. The memory system 410 may store data processed by the central processing unit 430 or data input from the outside. The memory system 410 may include a memory 412 and a memory controller 414 and may have substantially the same configuration as that of the memory card 300 described with reference to FIG. 4A. The information processing system 400 may be provided as, for example, a memory card, a semiconductor disk device (Solid State Disk), a camera image processor (Camera Image Sensor), and other application chipsets. As an example, the memory system 410 may be configured as a semiconductor disk device (SSD). In this case, the information processing system 400 may stably and reliably store a large amount of data in the memory system 410.

According to the embodiments of the inventive concept, the punch through and the DIBL can be improved by the insulating pattern without the halo region. It can prevent the electric field from increasing in the vicinity of the channels due to the halo region. Furthermore, it can restrain the junction leakage in the source/drain region and between the substrates

The embodiments of the inventive concept have been described by referring to the accompanying drawings. However, it is apparent to those skilled in the art that the inventive concept may be changed or modified in various forms within the scope of the inventive concept without departing from the spirit and scope of the appended claims. Therefore, it is understood that the above-described embodiments are exemplary in all respects and are not intended as limitations.

1. A semiconductor device, comprising:
a gate structure having a gate dielectric layer, a gate electrode, and a spacer, which are each formed on a substrate;
a first impurity area formed in a portion of the substrate located below the spacer;
a second impurity area in contact with a sidewall of the first impurity area and formed in the substrate on both sides of the gate structure; and
a dielectric pattern in contact with a portion of the first impurity area and formed on a sidewall of the second impurity area,
wherein the second impurity area includes an upper part with an upward-narrowing width and a lower part with a downward-narrowing width.

2. The semiconductor device of claim 1, wherein the dielectric pattern includes a material selected from the group consisting of oxides, nitrides, or oxynitrides.

3. The semiconductor device of claim 1, wherein the upper part of the second impurity area has a positive sidewall slope and the lower part of the second impurity area has a negative sidewall slope.

4. The semiconductor device of claim 3, wherein the first impurity area contacts with an upper sidewall of the second impurity area, and
the dielectric pattern is formed on a lower sidewall of the second impurity area and is in contact with a lower portion of the first impurity area.

5. The semiconductor device of claim 1, wherein a depth of the second impurity area is deeper than a depth of the first impurity area.

6. The semiconductor device of claim 1, wherein the first impurity area and the second impurity area each include a same conductive impurity.

7. The semiconductor device of claim 6, wherein the substrate includes a conductive impurity different from the conductive impurity of the first impurity area.

8-20. (canceled)
